(19) United States
(12) Patent Application Publication
(10) Pub. No.: US 2025/0343192 A1
(43) Pub. Date: Nov. 6, 2025

(54) SEMICONDUCTOR PACKAGE AND METHOD OF FORMING THE SAME

(71) Applicant: Taiwan Semiconductor Manufacturing Co., Ltd., Hsinchu (TW)

(72) Inventors: Yao-Jen Chang, Hsinchu (TW); Chung-Yu Lu, Hsinchu (TW); Ping-Kang Huang, Chiayi City (TW); Sao-Ling Chiu, Hsinchu (TW); Hsien-Pin Hu, Zhubei City (TW)

(21) Appl. No.: 19/269,947

(22) Filed: Jul. 15, 2025

Related U.S. Application Data
(63) Continuation of application No. 18/433,908, filed on Feb. 6, 2024.
(60) Provisional application No. 63/596,087, filed on Nov. 3, 2023.

(51) Int. Cl. H01L 23/00; H01L 23/498; H01L 25/065

(52) U.S. Cl. CPC H01L 24/13; H01L 23/49816; H01L 23/49838; H01L 24/05; H01L 25/0655; H01L 2224/05009; H01L 2224/05147; H01L 2224/13025; H01L 2224/13147; H01L 2924/01027; H01L 2924/01028; H01L 2924/01029; H01L 2924/15311

(57) ABSTRACT

A method includes forming a first conductive pillar on an interposer; forming a second conductive pillar on the interposer, wherein the second conductive pillar includes a barrier layer; bonding a first semiconductor device to the first conductive pillar by a first bonding region that includes more inter-metallic compound than solder; and bonding the first semiconductor device to the second conductive pillar by a second bonding region that includes more solder than inter-metallic compound.

### PRIORITY CLAIM AND CROSS-REFERENCE

This application is a continuation of U.S. patent application Ser. No. 18/433,908, filed on Feb. 6, 2024, which claims the benefits of U.S. Provisional Application No. 63/596,087, filed on Nov. 3, 2023, each application is hereby incorporated herein by reference in its entirety.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, and 10 illustrate cross-sectional views of intermediate steps in the formation of an interposer, in accordance with some embodiments.

FIGS. 11 and 12 illustrate cross-sectional views of intermediate steps in the formation of a package, in accordance with some embodiments.

FIG. 13 illustrates a magnified cross-sectional view of an intermediate step in the formation of a package, in accordance with some embodiments.

FIG. 14 illustrates a plan view of an intermediate step in the formation of a package, in accordance with some embodiments.

FIG. 15 illustrates a magnified cross-sectional view of an intermediate step in the formation of a package, in accordance with some embodiments.

FIG. 16 illustrates a magnified cross-sectional view of an intermediate step in the formation of a package, in accordance with some embodiments.

FIG. 17 illustrates a cross-sectional view of an intermediate step in the formation of a package, in accordance with some embodiments.

FIGS. 18 and 19 illustrate cross-sectional views of intermediate steps in the formation of a package, in accordance with some embodiments.

FIG. 20 illustrates a cross-sectional view of a package attached to a package substrate, in accordance with some embodiments.

FIG. 21 illustrates a cross-sectional view of a package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, components of the package are physically and electrically connected using multiple types of connections. For example, the different types of connections include connections at which the components are joined by fully inter-metallic compound (IMC) regions and connections at which the components are joined by partially IMC regions. In some cases, a single component (e.g. a die, semiconductor device, or the like) is connected by both mostly IMC connections and by mostly solder connections. In some cases, the mostly IMC connections can provide improved tolerance to current density, while the mostly solder connections can provide improved tolerance to stress. In this manner, using both types of connections where appropriate within a package can improve performance and reliability of the package.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

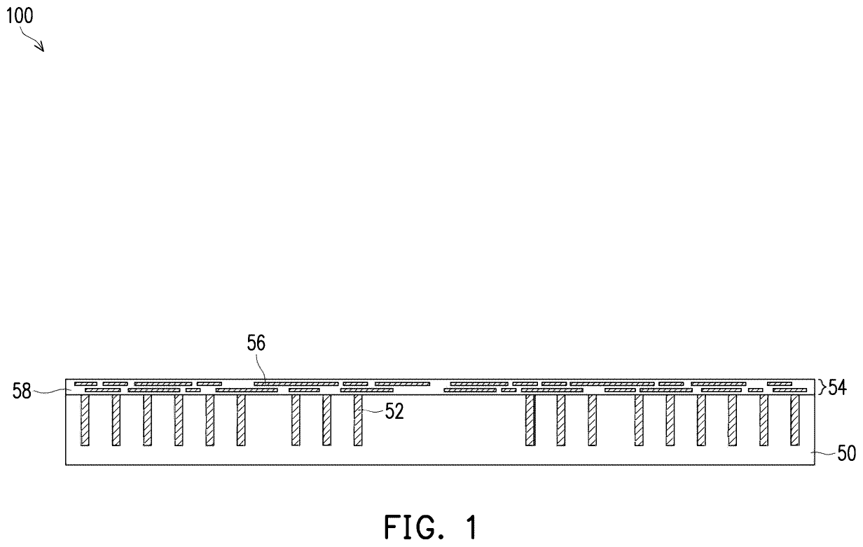

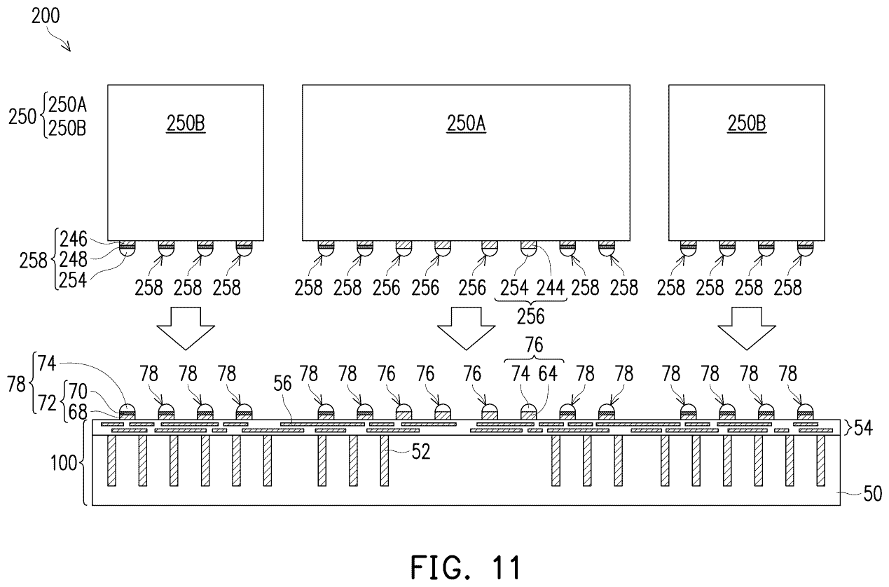

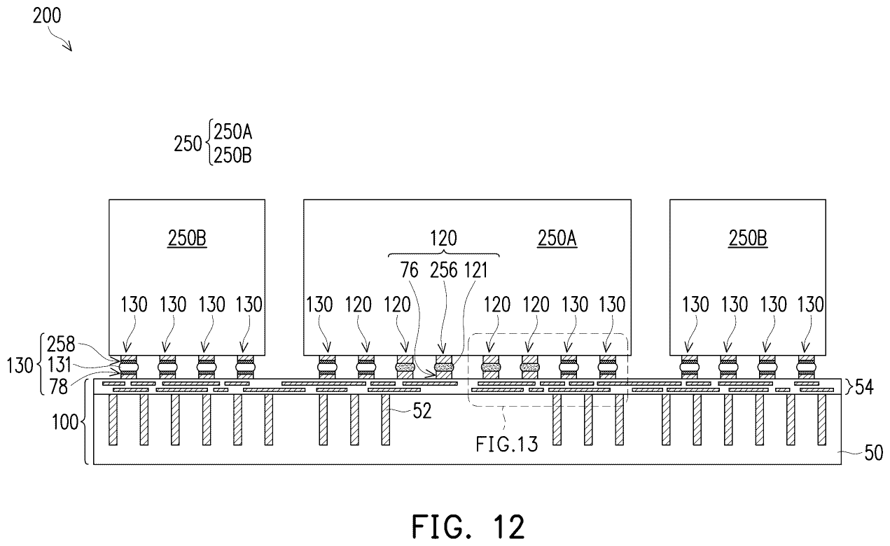

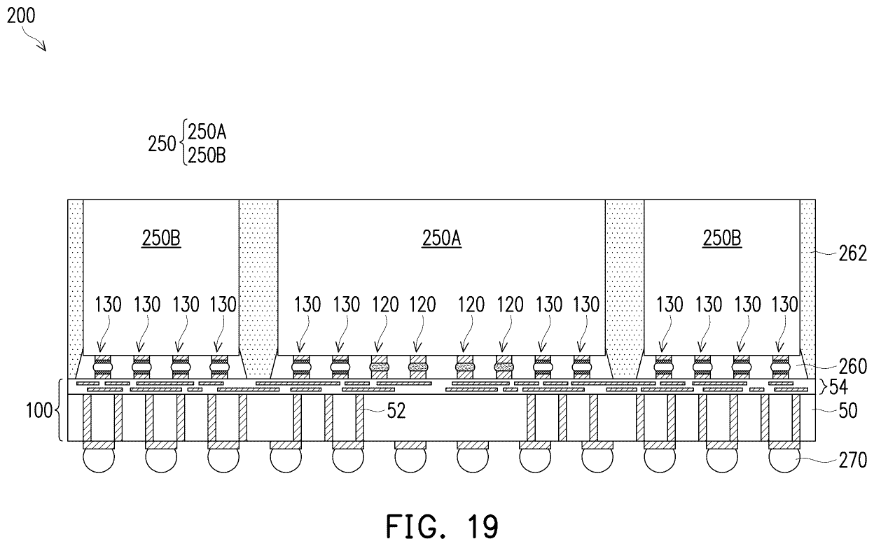

FIGS. 1-19 are various views of intermediate stages in the manufacturing of a package 200 (see FIG. 19), in accordance with some embodiments. Specifically, a package 200 is formed by bonding semiconductor devices 250 to an interposer 100 (see FIGS. 11-12). In some embodiments, the semiconductor devices 250 are bonded using two types of connections: first connections 120 comprising a fully inter-metallic compound (IMC) bonding region 121 and second connections 130 comprising a partially IMC bonding region 131. Using different types of connections in the same package as described herein can allow for improved stress tolerance, improved thermal performance, and improved high current operation. In an embodiment, the package 200 is a chip-on-wafer (CoW) package, although it should be appreciated that embodiments may be applied to other three-dimensional integrated circuit (3DIC) packages. In an embodiment, the package 200 may be a part of a larger package, such as a chip-on-wafer-on-substrate (CoWoS) package or the like, although it should be appreciated that embodiments may be applied to other 3DIC packages. The embodiments of FIGS. 1-20 are described using the context of an interposer 100, but it should be appreciated that the embodiments herein may be applied to another structure, such as a silicon wafer, a carrier substrate, an organic core substrate, a die, a chip, a package, or any other suitable structure.

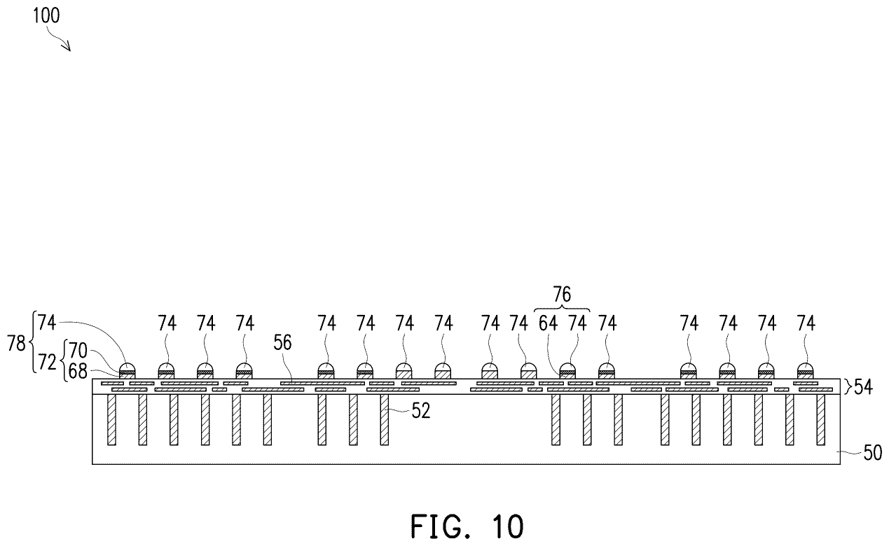

FIGS. 1 through 10 illustrate intermediate steps in the formation of an interposer 100 (see FIG. 10), in accordance with some embodiments. The interposer 100 comprises an interconnect structure 54 on a substrate 50, in accordance with some embodiments. The substrate 50 may be a wafer, such as a silicon wafer, in some embodiments. Other substrates, such as a silicon-on-insulator (SOI) substrate, a multi-layered substrate, or a gradient substrate may also be used. The substrate 50 may be doped (e.g., with a p-type or an n-type dopant) or undoped. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 50 may be a dielectric material such as silicon oxide, glass, ceramic, plastic, or any other suitable material that allows for structural support of overlying devices. In some embodiments, multiple interposers 100 may be formed on a single substrate 50 and then may be subsequently singulated into individual interposers 100 or individual packages. In some embodiments, active devices (e.g., transistors, diodes, or the like), passive devices (e.g. capacitors, resistors, or the like), integrated circuits, and/or the like may be formed in the substrate 50. The substrate 50 may be free of passive or active devices, in other embodiments.

In some embodiments, the interposer 100 comprises through vias 52 extending into the substrate 50. The through vias 52 are electrically connected to the interconnect structure 54. The through vias 52 may be formed, for example, by forming openings extending into the substrate 50. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the through vias 52. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the substrate 50 such that surfaces of the through vias 52 and the substrate 50 are level. The through vias 52 may protrude from the substrate 50 and into the interconnect structure 54, in other embodiments. Other materials or techniques are possible.

The interconnect structure 54 comprises one or more layers of conductive features 56 formed in one or more dielectric layers 58 (not individually illustrated), in some embodiments. The conductive features 56 may comprise conductive lines, conductive vias, conductive pads, metallization patterns, redistribution layers, or the like that provide electrical interconnections and electrical routing. In some embodiments, the conductive features 56 comprise conductive pads (not illustrated) at a top surface of the interconnect structure 54, such as in a top dielectric layer 58. The conductive pads may be Under-Bump Metallizations (UBMs), or the like. In some embodiments, the interconnect structure 54 may have multiple layers of conductive features 56, but the precise number of layers of conductive features 56 may be dependent upon the design of the interconnect structure 54. The conductive features 56 may be formed using any suitable techniques such as deposition, damascene, dual damascene, or the like. The conductive features 56 may include, for example, a metal or a metal alloy such as copper, silver, gold, tungsten, cobalt, ruthenium, aluminum, alloys thereof, combinations thereof, or the like. Other materials are possible.

Acceptable dielectric materials for the dielectric layers 58 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The dielectric layers 58 may be formed using any suitable techniques. In some embodiments, the interconnect structure 54 may have multiple dielectric layers 58, but the precise number of dielectric layers 58 may be dependent upon the design of the interconnect structure 54.

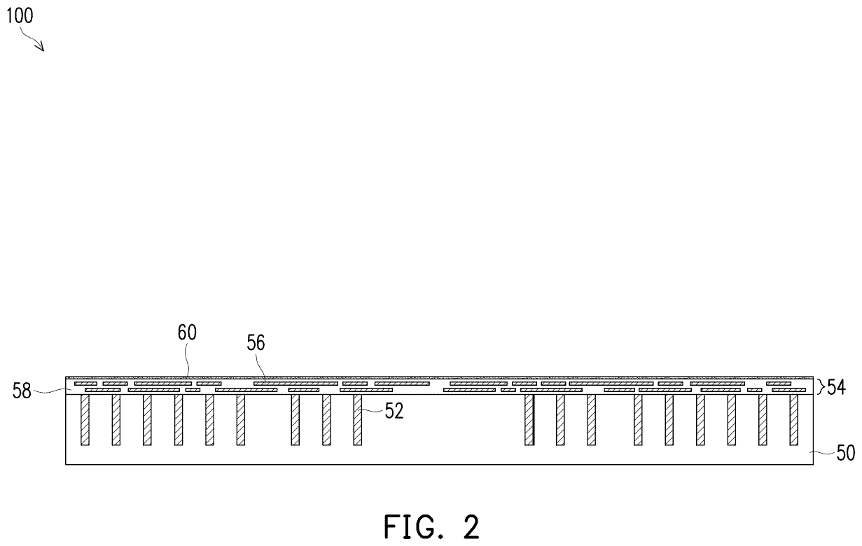

In FIG. 2, a seed layer 60 is formed over the interconnect structure 54, in accordance with some embodiments. The seed layer 60 may be formed on a top dielectric layer 58 and may be formed on exposed surfaces of conductive features 56. For example, in some embodiments, prior to forming the seed layer 60, conductive features 56 (not individually illustrated) of the interconnect structure 54 are exposed by patterning overlying dielectric layer(s) 58. The overlying dielectric layer(s) 58 may be patterned using a suitable photolithography and etching process. In some cases, the exposed conductive features 56 are conductive pads, UBMs, or the like. In some embodiments, the seed layer 60 is a metal layer, which may be a single layer or a composite layer including a plurality of sub-layers formed of different materials. In some embodiments, the seed layer 60 includes a titanium layer and a copper layer over the titanium layer. The seed layer 60 may be formed using, for example, PVD or the like.

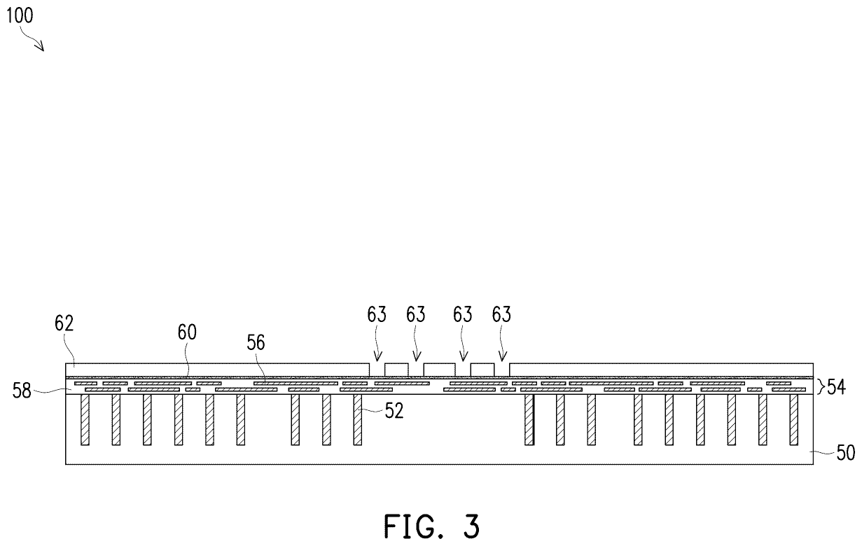

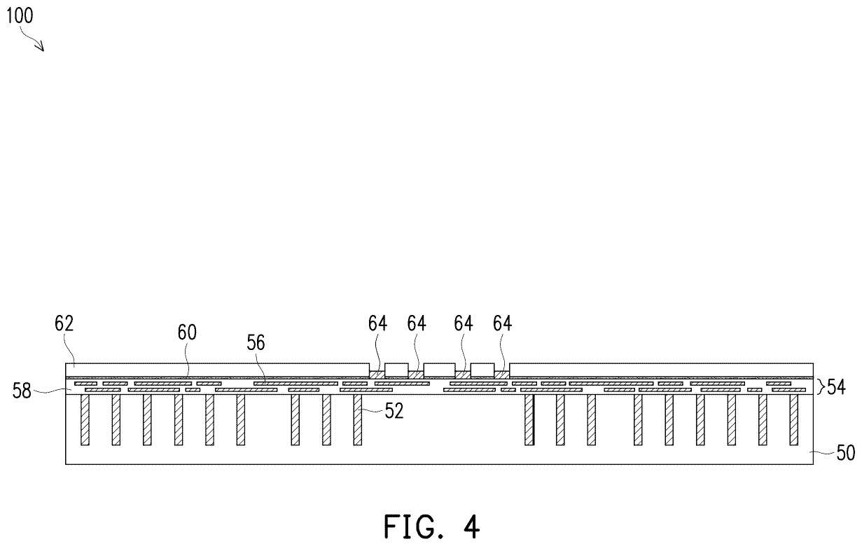

FIGS. 3-5 illustrate the formation of first pillars 64 (see FIG. 4), in accordance with some embodiments. In FIG. 3, a first plating mask 62 is formed over the seed layer 60, in accordance with some embodiments. The first plating mask 62 may be formed of a patterned photoresist, in some embodiments. The photoresist may be formed by spin coating or the like and may be exposed to light for patterning. The pattern of the photoresist corresponds to subsequently formed first pillars 64 (see FIG. 4). The pattern forms openings 63 through the photoresist to expose the seed layer 60. In some cases, the openings 63 may expose portions of the seed layer 60 that were deposited on conductive features 56.

In FIG. 4, a conductive material is deposited in the openings 63 to form first pillars 64, in accordance with some embodiments. The conductive material may be formed on the portions of the seed layer 60 exposed by the openings 63. The conductive material may be formed by plating, such as electroplating or electroless plating, or the like. The conductive material may comprise a metal or a metal alloy, such as copper, titanium, tungsten, aluminum, the like, or combinations thereof. The conductive material and underlying portions of the seed layer 60 form the first pillars 64. In some embodiments, the first pillars 64 are formed having a height in the range of about 10 μm to about 40 μm, though other heights are possible. In some embodiments, the first pillars 64 have substantially vertical sidewalls.

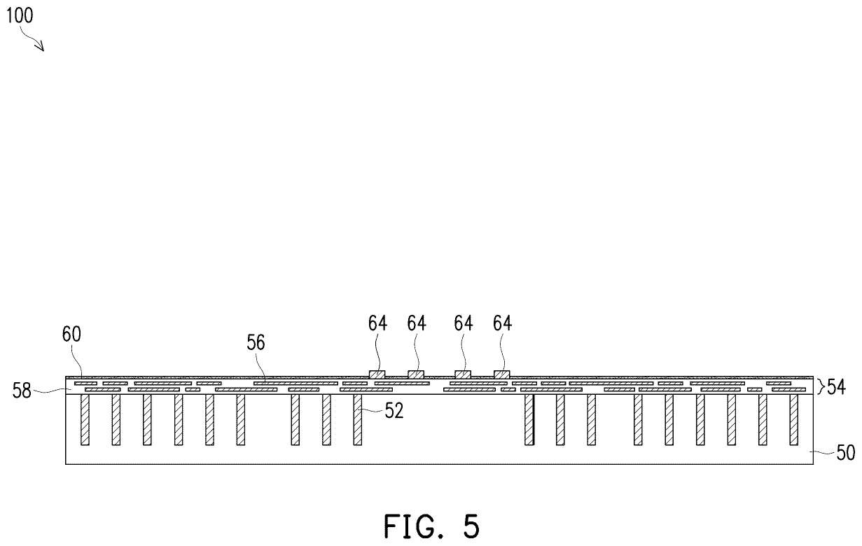

In FIG. 5, the first plating mask 62 is removed, in accordance with some embodiments. As an example, for embodiments in which the first plating mask 62 is a photoresist, the photoresist may be removed using an acceptable ashing or stripping process, such as using an oxygen plasma or the like. In some embodiments, portions of the seed layer 60 that were covered by the first plating mask 62 remain after the first plating mask 62 has been removed, as shown in FIG. 5. In other embodiments, portions of the seed layer 60 that were covered by the first plating mask 62 are removed after the first plating mask 62 has been removed. In such embodiments, the exposed portions of the seed layer 60 may be removed using a suitable etching process, such as a wet etching process and/or a dry etching process.

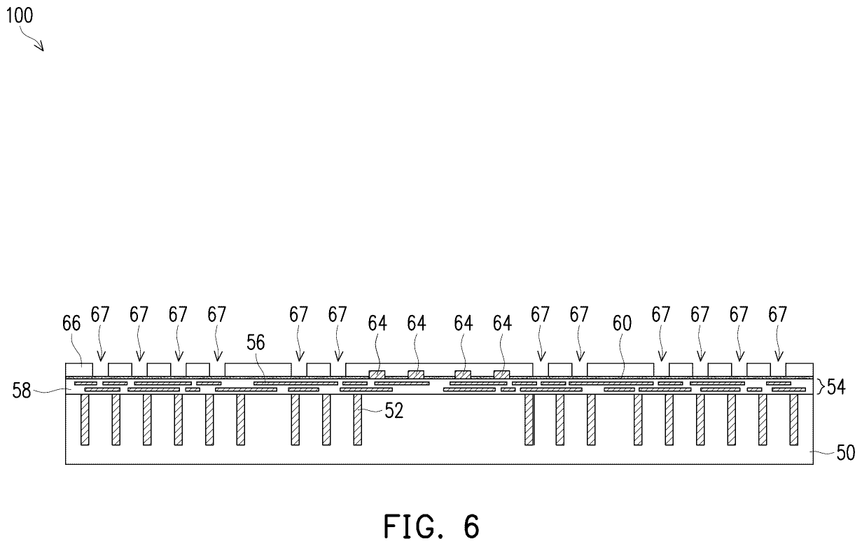

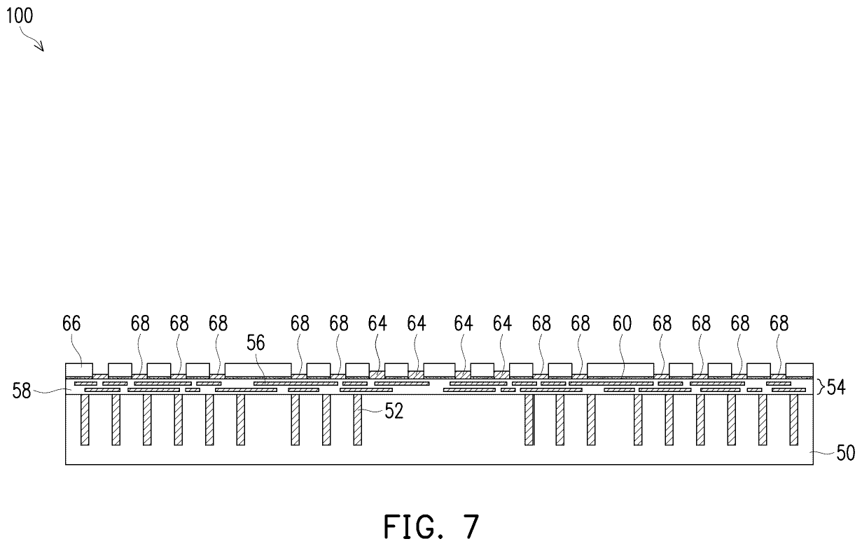

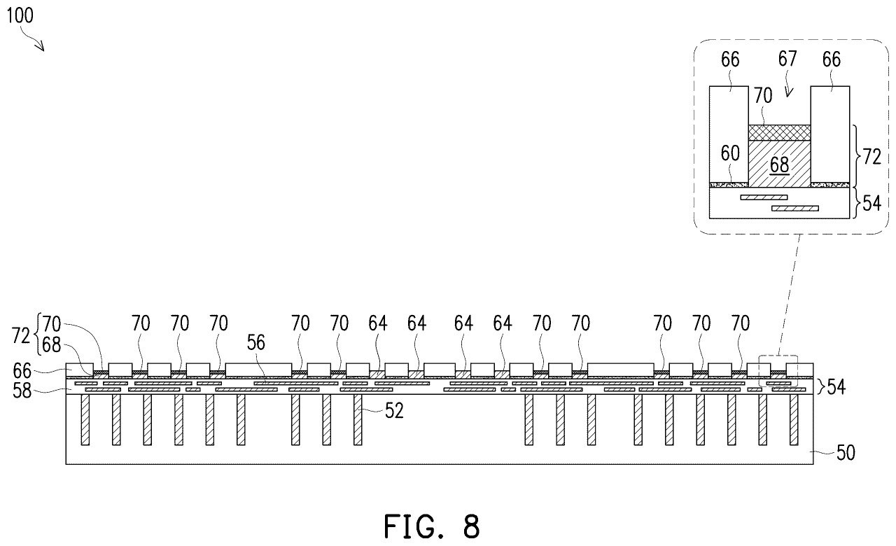

FIGS. 6-9 illustrate the formation of barrier pillars 72 (see FIG. 8), in accordance with some embodiments. In other embodiments, the barrier pillars 72 are formed before the first pillars 64. In FIG. 6, a second plating mask 66 is formed over the seed layer 60, in accordance with some embodiments. The second plating mask 66 may be formed of a patterned photoresist, in some embodiments. The photoresist may be formed by spin coating or the like and may be exposed to light for patterning. The pattern of the photoresist corresponds to subsequently formed second pillars 68 (see FIG. 7) of barrier pillars 72 (see FIG. 8). The pattern forms openings 67 through the photoresist to expose the seed layer 60. In some cases, the openings 67 may expose portions of the seed layer 60 that were deposited on conductive features 56. In other embodiments, such as embodiments in which exposed portions of the seed layer 60 are removed, a second seed layer may be deposited over the interconnect structure 54 before forming the second plating mask 66. In such embodiments, the second seed layer may be similar to the first seed layer 60.

In FIG. 7, a conductive material is deposited in the openings 67 to form second pillars 68, in accordance with some embodiments. The conductive material may be formed on the portions of the seed layer 60 exposed by the openings 67. The conductive material may be formed by plating, such as electroplating or electroless plating, or the like. The conductive material may comprise a metal or a metal alloy, such as copper, titanium, tungsten, aluminum, the like, or combinations thereof. The conductive material may be similar to the conductive material of the first pillars 64, in some cases. In some embodiments, the second pillars 68 are formed having a height in the range of about 5 μm to about 30 μm, though other heights are possible. In some embodiments, the second pillars 68 have substantially vertical sidewalls. In some embodiments, a height of the second pillars 68 is less than a height of the first pillars 64. In other embodiments, the first pillars 64 and the second pillars 68 are formed using the same deposition process using the same patterned plating mask.

In FIG. 8, a barrier layer 70 is formed on the second pillars 68 to form barrier pillars 72, in accordance with some embodiments. FIG. 8 includes a magnified cross-sectional view of a portion of the structure. The barrier layer 70, the second pillars 68, and underlying portions of the seed layer 60 form the barrier pillars 72. The barrier layer 70 comprises a conductive material that suppresses inter-metal diffusion, and thus can suppress the subsequent formation of inter-metallic compound (IMC) on the second pillars 68. In some embodiments, the barrier layer 70 comprises a conductive material such as cobalt, nickel, the like, or a combination thereof. In other embodiments, barrier layers of different materials may be deposited on different second pillars 68. The barrier layer 70 may be deposited using a suitable technique, such as plating (e.g., electroplating or electroless plating) or another technique. In some embodiments, a thickness of the barrier layer 70 is in the range of about 5 μm to about 20 μm, though other thicknesses are possible. In some embodiments, a height of the barrier pillars 72 is about the same as a height of the first pillars 64. In other embodiments, a height of the barrier pillars 72 is greater than or less than a height of the first pillars 64.

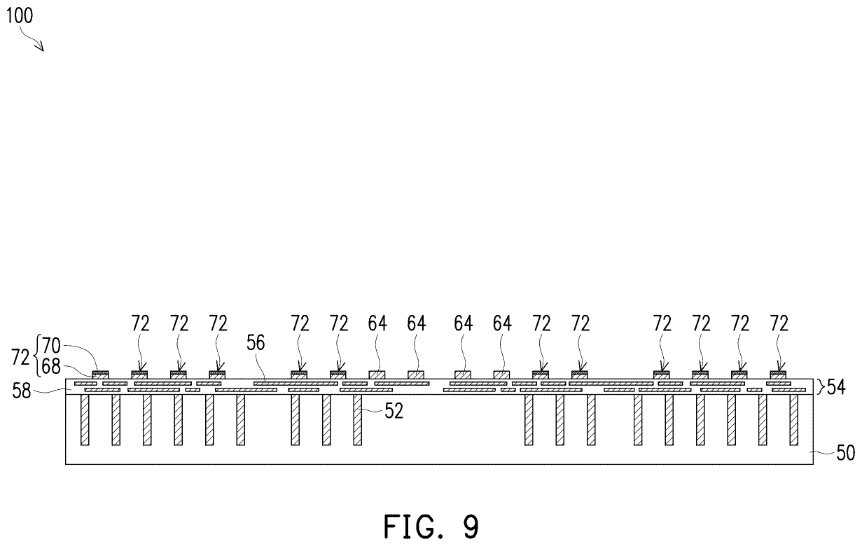

In FIG. 9, the second plating mask 66 is removed, in accordance with some embodiments. As an example, for embodiments in which the second plating mask 66 is a photoresist, the photoresist may be removed using an acceptable ashing or stripping process, such as using an oxygen plasma or the like. Additionally, portions of the seed layer 60 that were covered by the second plating mask 66 are removed after the second plating mask 66 has been removed. In such embodiments, the exposed portions of the seed layer 60 may be removed using a suitable etching process, such as a wet etching process and/or a dry etching process. In some cases, the etching process uses the first pillars 64 and the barrier pillars 72 as an etching mask when etching the seed layer 60.

In FIG. 10, solder material 74 is formed on the first pillars 64 to form first connectors 76 and on the barrier pillars 72 to form barrier connectors 78, in accordance with some embodiments. The solder material 74 may include a solder layer, solder balls, solder bumps, or the like. The solder material 74 may include a conductive material such as solder, silver, tin, the like, or a combination thereof. In some embodiments, the solder material 74 is formed through evaporation, electroplating, printing, solder transfer, ball placement, stenciling, or the like. In some embodiments, once the solder material 74 is formed on the first pillars 64 and on the barrier pillars 72, a reflow process may be performed in order to shape the solder material 74 into the desired bump shapes. In some embodiments, the reflow process causes the solder material 74 and the first pillars 64 to inter-diffuse and form an inter-metallic compound (IMC) within the first connectors 76. For example, in embodiments in which the first pillars 64 comprise copper and the solder material 74 comprises tin, the IMC may comprise CuSn (e.g., Cu₃Sn, Cu₆Sn₅, or the like). In such embodiments, the presence of the barrier layer 70 reduces or prevents inter-diffusion between the solder material 74 and the second pillars 68, and thus little or no IMC is formed within the barrier connectors 78. In some cases, the first connectors 76 and the barrier connectors 78 may be micro bumps or the like. In some embodiments, because a barrier layer is not formed on the first pillars 64, the first connectors 76 may be considered “barrier-free” connectors.

FIGS. 11-19 are various views of intermediate stages in the manufacturing of a package 200 (see FIG. 19), in accordance with some embodiments. In FIGS. 11-12, semiconductor devices 250 (e.g., semiconductor devices 250A and 250B) are bonded to the interposer 100, in accordance with some embodiments. FIG. 11 illustrates the semiconductor devices 250 prior to bonding, and FIG. 12 illustrates the semiconductor devices 250 after bonding. The semiconductor devices 250 shown in FIGS. 11-12 are examples, and semiconductor devices 250 may have different numbers, arrangements, types, dimensions, or other characteristics than described herein.

The semiconductor devices 250 may include, for example, a chip, a die, a system-on-chip (SoC) device, a system-on-integrated-circuit (SoIC) device, a package, the like, or a combination thereof. In some embodiments, the semiconductor devices 250 comprise logic dies, memory dies, input-output (I/O) dies, Integrated Passive Devices (IPDs), or the like, or combinations thereof. For example, the semiconductor devices 250 may comprise logic dies such as Central Processing Unit (xPU or CPU) dies, Graphic Processing Unit (GPU) dies, mobile application dies, Micro Control Unit (MCU) dies, BaseBand (BB) dies, Application processor (AP) dies, Application-Specific Integrated Circuit (ASIC) dies, a high performance computing (HPC) die, or the like. The semiconductor devices 250 may comprise memory dies such as Static Random-Access Memory (SRAM) dies, Dynamic Random-Access Memory (DRAM) dies, High-Performance Memory (HBM) dies, or the like. Other types of semiconductor devices 250 are possible. FIGS. 11-12 show two types of semiconductor devices 250, represented by semiconductor devices 250A and semiconductor devices 250B. For example, in some embodiments, the semiconductor devices 250A may be logic dies and the semiconductor devices 250B may be memory dies. This is an example, and other numbers, types, arrangements, configurations, or combinations are possible.

The semiconductor devices 250 comprise first connectors 256 and/or barrier connectors 258, in accordance with some embodiments. The first connectors 256 may be similar to the first connectors 76 described for the interposer 100, and the barrier connectors 258 may be similar to the barrier connectors 78 described for the interposer 100, in some embodiments. For example, the first connectors 256 may comprise a solder material 254 on conductive pillars 244, which may be similar to the solder material 74 and first pillars 64 of the first connectors 76. Accordingly, the first connectors 256 may be “barrier-free,” similar to the first connectors 76. The barrier connectors 258 may comprise a barrier layer 248 between conductive pillars 246 and solder material 254, which may be similar to the barrier layer 70, second pillars 68, and solder material 74 of the barrier connectors 78. For example, in some embodiments, the barrier layer 248 may comprise cobalt, nickel, or the like. The conductive pillars 246 and the barrier layer 248 form barrier pillars 249. In other embodiments, solder material 254 is not formed on the first connectors 256 and/or the barrier connectors 258. The first connectors 256 and the barrier connectors 258 may be formed using suitable materials and techniques, including those described previously for forming the first connectors 76 or barrier connectors 78.

A single semiconductor device 250 may have first connectors 256, barrier connectors 258, or a combination thereof. For example, in FIG. 11, the semiconductor device 250B has only barrier connectors 258, but the semiconductor device 250A has both first connectors 256 and barrier connectors 258. A semiconductor device 250 may have only first connectors 256, in some cases. In some embodiments, first connectors 256 of a semiconductor device 250 are subsequently bonded to corresponding first connectors 76 of an interposer 100, and barrier connectors 258 of a semiconductor device 250 are subsequently bonded to corresponding barrier connectors 78 of an interposer 100. As described below, the use of different types of connectors (76, 78, 256, and/or 258) within the same package can improve stress tolerance.

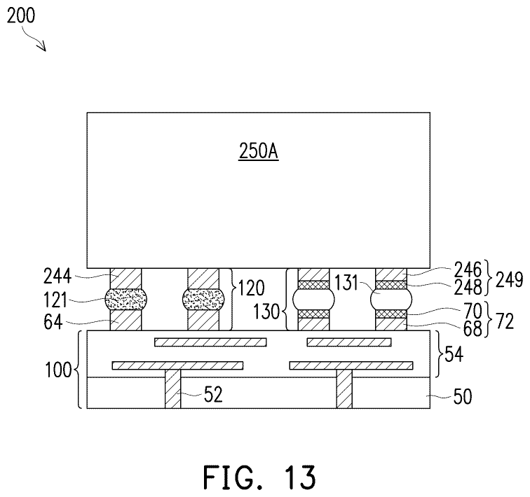

In FIG. 12, the semiconductor devices 250 are bonded to the interposer 100, in accordance with some embodiments. FIG. 13 illustrates a magnified portion of the structure, as indicated in FIG. 12. The first connectors 256 of semiconductor devices 250 are aligned and placed into contact with corresponding first connectors 76 of the interposer 100, and barrier connectors 258 of the semiconductor device 250 are aligned and placed into contact with corresponding barrier connectors 78 of the interposer 100. Then, a reflow process may be performed to bond the first connectors 256 to the first connectors 76 and to bond the barrier connectors 258 to the barrier connectors 78. The reflow process melts solder material (e.g., solder material 74/254), forming bonding regions 121 that join first connectors 76 to first connectors 256 and forming bonding regions 131 that join barrier connectors 78 to barrier connectors 258. The first connectors 76, first connectors 256, and bonding regions 121 collectively form first connections 120, and the barrier connectors 78, barrier connectors 258, and bonding regions 131 collectively form second connections 130. In other embodiments, the first connectors 76 and/or the barrier connectors 78 are part of a local silicon interconnect (LSI) or chiplet within the interposer 100.

In some embodiments, inter-metal diffusion between the solder material 74/254 and the pillars 76/256 forms a bonding region 121 substantially comprising an inter-metallic compound (IMC). For example, in some embodiments, the bonding region 121 may comprise an IMC such as Cu₃Sn, Cu₆Sn₅, the like, or a combination thereof. In some embodiments, all of the solder material 74/254 may react such that the bonding regions 121 of the first connections 120 are completely formed of an IMC. Accordingly, the bonding region 121 may also be referred to herein as an IMC bonding region 121 or an IMC region 121. Thus, the first connections 120 may also be referred to herein as IMC connections 120, “mostly IMC” connections 120, or “fully IMC” connections 120 in some cases. In some embodiments, the bonding regions 121 comprise between about 90% and about 100% IMC region.

In some embodiments, the barrier layers 70/248 of the barrier connectors 78/258 suppress inter-metal diffusion such that little or no IMC is formed in the bonding regions 131 of the second connections 130. In this manner, the bonding regions 131 may be solder-rich regions that substantially comprise unreacted solder material 74/254, with little or no IMC present. In some embodiments, the bonding regions 131 comprise between about 90% and about 100% non-IMC solder. In other words, in some embodiments, the bonding regions 131 comprise less than about 10% IMC. For example, in some embodiments, the atomic composition of the bonding regions 131 is between about 90% tin and about 100% tin. Other compositions or proportions are possible. Accordingly, the bonding regions 131 may also be referred to herein as a solder regions 131, “mostly solder” bonding regions 131, or “partially IMC” bonding regions 131 in some cases. Thus, the second connections 130 may also be referred to herein as solder connections 130, “mostly solder” connections 130, or “partially IMC” connections 130 in some cases.

In some embodiments, the first connections 120 and/or the second connections 130 have a height that is in the range of about 35 μm to about 60 μm. Accordingly, the average height of all of the connections 120/130 on an interposer 100 is in the range of about 35 μm to about 60 μm. In some embodiments, each connection 120/130 has a height that differs from the average height by no more than about 15% of the average height. In other words, in some embodiments, each connection 120/130 has a height that is between about 85% and about 115% of the average height. In some embodiments, the sum of a height of a first pillar 64 and a height of the corresponding first pillar 244 is between about 35% and about 60% of the total height of the connection 120. In some embodiments, the sum of a height of a barrier pillar 72 and a height of the corresponding barrier pillar 249 is between about 35% and about 60% of the total height of the connection 120. Other heights or proportions are possible.

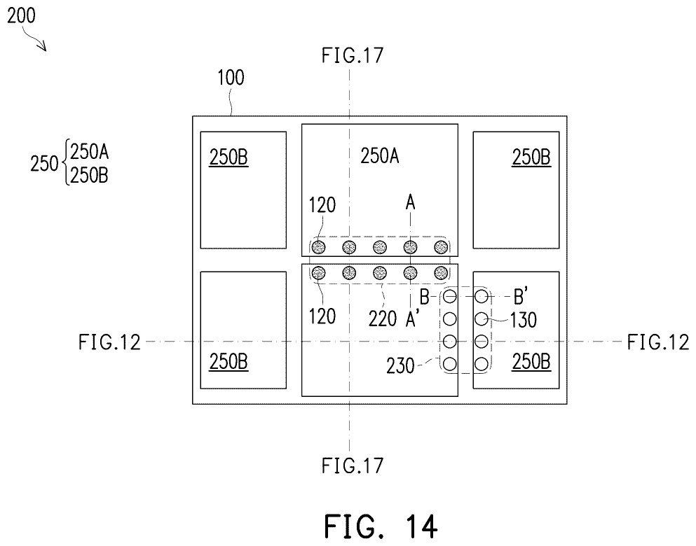

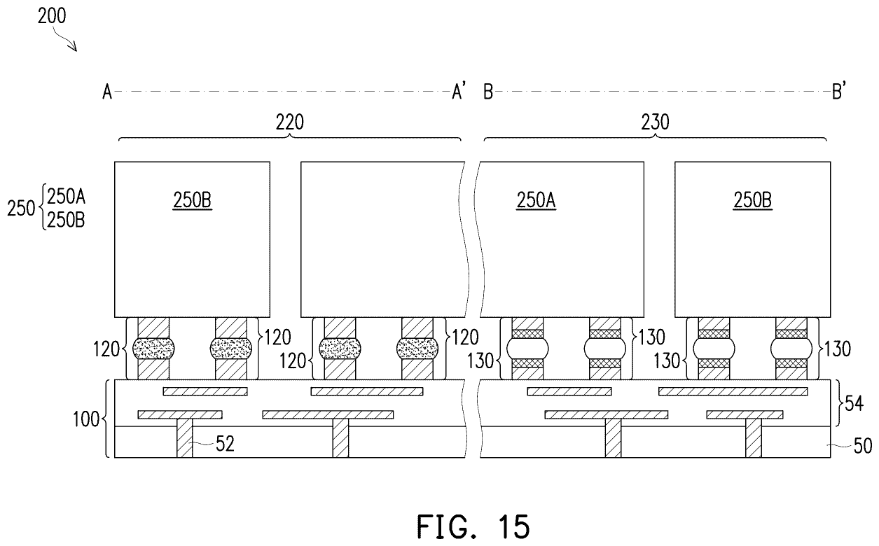

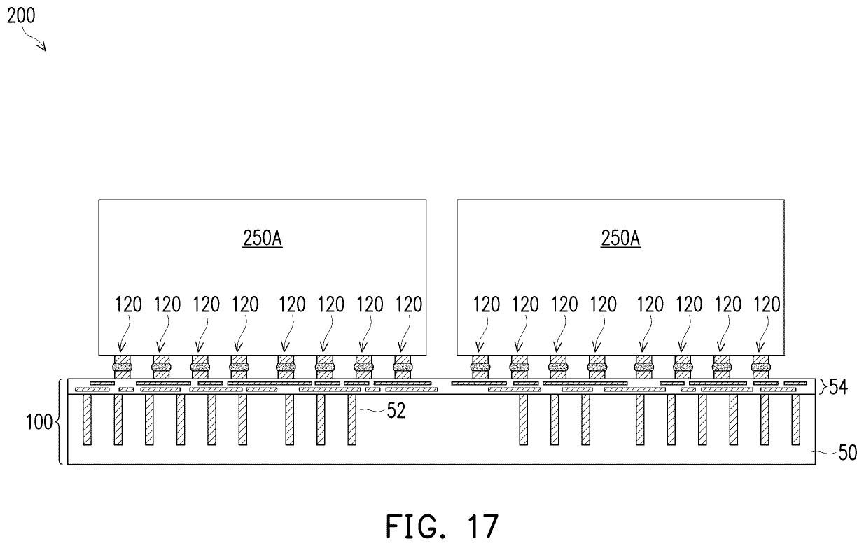

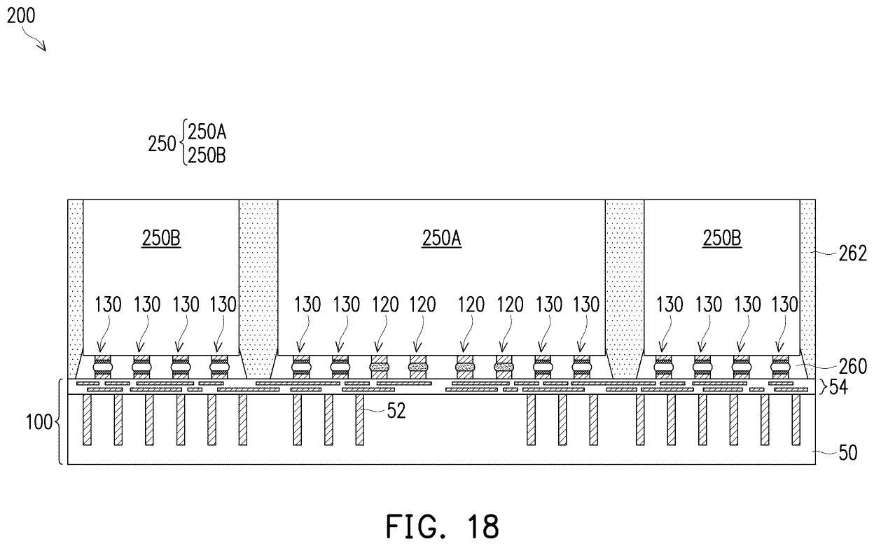

FIG. 14 illustrates a schematic plan view of a structure similar to that shown in FIG. 12, in accordance with some embodiments. Accordingly, the plan view of FIG. 14 may also correspond to the subsequently-formed package 200 (see FIG. 18). FIG. 12 illustrates a cross-sectional view along a cross-section similar to the reference cross-section FIG. 12 indicated in FIG. 14. FIG. 17 illustrates a cross-sectional view along a cross-section similar to the reference cross-section FIG. 17 indicated in FIG. 14. Additionally, FIG. 15 illustrates cross-sectional views of the structure of FIG. 14 along the reference cross-sections A-A′ and B-B′. For clarity, not all features are illustrated in FIG. 14. For example, representative connections 120 and 130 are shown in FIG. 14 for explanatory purposes, but it should be appreciated that more connections 120/130 may be present in the structure. FIG. 14 illustrates a structure comprising two adjacent semiconductor devices 250A, with each semiconductor device 250A being adjacent two semiconductor devices 250B. For example, in some embodiments, the semiconductor devices 250A may be SoC dies, and the semiconductor devices 250B may be memory dies. The structure shown in FIG. 14 is an example, and other types, arrangements, numbers, configurations, or dimensions of semiconductor devices 250 are possible.

As shown in FIG. 14, electrical connections between adjacent semiconductor devices 250A are made through the interposer 100 using IMC connections 120, and electrical connections between adjacent semiconductor devices 250A and semiconductor devices 250B are made through the interposer 100 using solder connections 130. In some embodiments, solder connections 130 are used in relatively higher stress regions of the structure, an approximate example of which is indicated as high-stress region 230. In some cases, the high-stress regions 230 may include regions adjacent to two semiconductor devices 250, such as regions between a semiconductor devices 250A and adjacent semiconductor devices 250B, as shown in FIG. 14. In some cases, the high-stress regions 230 may include regions relatively close to the edge of the structure. The high-stress region 230 shown in FIG. 14 is an example, and other numbers, locations, sizes, or shapes of high-stress regions 230 are possible.

In some embodiments, solder connections 130 may be used to connect semiconductor devices 250 to the interposer 100 in the high-stress regions 230. In some embodiments, the use of solder connections 130 in high-stress regions 230 can improve stress tolerance and robustness to thermal shock in these regions. In this manner, the reliability and performance of a package may be improved. In some embodiments, a semiconductor device 250 within a high-stress region 230 may be connected to the interposer 100 only by solder connections 130, but in other embodiments, a semiconductor device 250 may be connected using both IMC connections 120 and solder connections 130.

In some embodiments, IMC connections 120 may be used in relatively lower stress regions of the structure. An approximate example of a relatively lower stress region is indicated in FIG. 14 by low-stress region 220. In some cases, the low-stress regions 220 may include regions adjacent to two semiconductor devices 250, such as regions between adjacent semiconductor devices 250A as shown in FIG. 14. In some cases, low-stress regions 220 may be relatively close to the center of the structure. The low-stress region 220 shown in FIG. 14 is an example, and other numbers, locations, sizes, or shapes of low-stress regions 220 are possible.

In some embodiments, IMC connections 120 may be used to connect semiconductor devices 250 to the interposer 100 in the low-stress regions 220. Because the IMC connections 120 comprise fully IMC bonding regions 121, IMC connections 120 may permit higher current densities than solder connections 130. In some embodiments, the use of IMC connections 120 in low-stress regions 220 can allow for higher current densities and improved electromagnetic properties in these regions. In this manner, the reliability and performance of a package may be improved. Additionally, in some cases, IMC connections 120 may be used in other regions where high current densities are required. In some embodiments, a semiconductor device 250 within a low-stress region 220 may be connected to the interposer 100 using both IMC connections 120 and solder connections 130. For example, the semiconductor devices 250A in FIG. 14 are connected by both IMC connections 120 and solder connections 130, with electrical connections to adjacent semiconductor devices 250A being through IMC connections 120 and electrical connections to adjacent semiconductor devices 250B being through solder connections 130. In some embodiments, the IMC connections 120 may be located near edges of semiconductor devices 250 that are relatively closer to the center of the structure, though IMC connections 120 may be in any suitable locations. In other embodiments, a semiconductor device 250 may be connected only by IMC connections 120. In some embodiments, a semiconductor device 250 may have IMC connections 120 adjacent one edge and solder connections 130 adjacent a different edge.

In some embodiments, a dummy solder connection 140 may be formed in a low-stress region 220 to provide additional structural support and thermal robustness. In some embodiments, a dummy solder connection 140 may be similar to a solder connection 130 described previously, except that the dummy solder connection 140 is not used to make electrical connection between a semiconductor device 250 and an interposer 100. A dummy solder connection 140 may be electrically isolated from functional conductive features of the semiconductor device 250 and/or the interposer 100, in some cases. The dummy solder connection 140 may be formed using materials or techniques similar to that of the solder connection 130 described previously. For example, in some embodiments, the solder connections 130 and the dummy solder connections 140 may be formed simultaneously using the same process steps. Accordingly, in some embodiments, the barrier pillars that form the dummy solder connections 140 may be considered dummy barrier pillars.

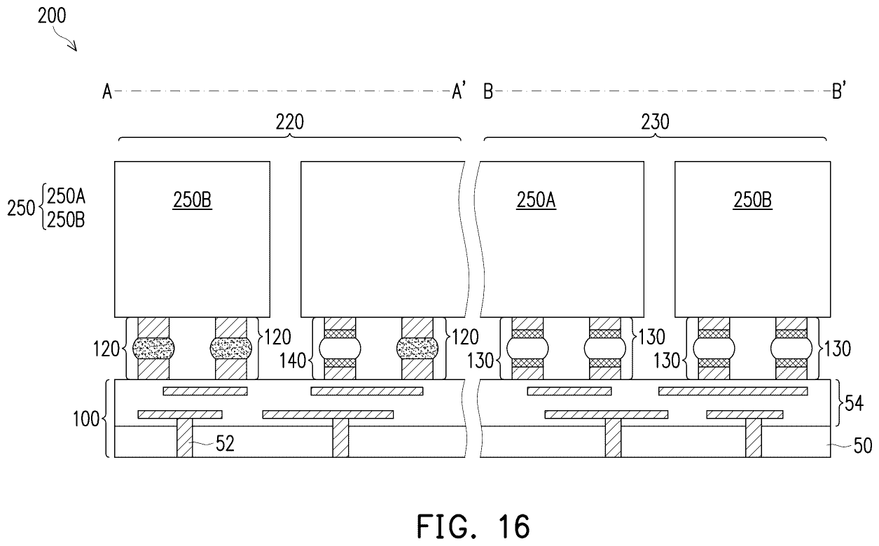

FIG. 16 illustrates cross-sectional views of a structure similar to that shown in FIG. 15, except a dummy solder connection 140 is used in place of a IMC connection 120. FIG. 16 is an illustrative example, and any suitable number of dummy solder connections 140 may be used in any suitable locations. For example, in other embodiments, dummy solder connection 140 may be used with both adjacent semiconductor devices 250A, or may be used in locations that are not near an edge of a semiconductor device 250A. In some embodiments, a dummy solder connection 140 may be used in place of or in addition to a IMC connection 120. Other arrangements of dummy solder connection 140 are possible.

In FIG. 18, the semiconductor devices 250 are encapsulated, in accordance with some embodiments. In some embodiments, an underfill 260 is dispensed into gaps between the semiconductor devices 250 and the interposer 100. In some cases, the underfill 260 may also be dispensed between neighboring semiconductor devices 250. In accordance with some embodiments, the underfill 260 includes a base material and filler particles mixed in the base material. The base material may be a resin, an epoxy, a polymer, the like, or a combination thereof. Some example base materials include epoxy-amine, epoxy anhydride, epoxy phenol, or the like, or a combination thereof. The filler particles may be formed of a dielectric material, and may include silica, alumina, boron nitride, the like, or a combination thereof. The filler particles may have spherical shapes or other shapes. In some embodiments, the underfill 260 is dispensed in a flowable form and is then cured. Other materials or deposition techniques are possible. In other embodiments, the underfill 260 is not present.

The semiconductor devices 250 are then encapsulated in an encapsulant 262, in accordance with some embodiments. The encapsulant 262 may be, for example, a molding compound, a molding underfill, an epoxy, a resin, the like, or a combination thereof. The encapsulant 262 may include a base material, and a filler in the base material. The base material may include a polymer material, which may be or may comprise a plastic, an epoxy resin (such as Epoxy Cresol Novolac (ECN), biphenyl epoxy resin, or a multifunctional liquid epoxy resin), polyimide, polyethylene terephthalate (PET), polyvinyl chloride (PVC), polymethylmethacrylate (PMMA), the like, or a combination thereof. The filler may include titanium dioxide, carbon black, calcium carbonate, silica, fiber, clay, ceramic, inorganic particles, the like, or a combination thereof, which may be in the form of filler particles.

In some embodiments, a planarization process is then performed to remove excess portions of the encapsulant 262. The planarization process may include, for example, a Chemical Mechanical Polish (CMP) process, a mechanical grinding process, the like, or a combination thereof. In some embodiments, the planarization process exposes one or more of the semiconductor device 250. In some embodiments, after performing the planarization process, top surfaces of the encapsulant 262 and one or more of the semiconductor devices 250 are level or coplanar.

In FIG. 19, conductive connectors 270 are formed on the interposer 100, in accordance with some embodiments. In some embodiments, a planarization process (e.g., a CMP or grinding process) may be performed on the substrate 50 to expose the through vias 52. In some embodiments, conductive features such as redistribution layers, UBMs, or the like (not illustrated) may then be formed over the substrate 50 and over the exposed through vias 52. In some embodiments, conductive connectors 270 are formed over the substrate 50 and over the exposed through vias 52. The conductive connectors 270 may be electrically connected to the through vias 52. The conductive connectors 270 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 270 may be formed of a conductive material that is reflowable, such as solder, copper, aluminum, gold, nickel, silver, palladium, tin, the like, or a combination thereof. In some embodiments, the conductive connectors 270 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the conductive connectors 270 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In this manner, a package 200 comprising both IMC connections 120 and solder connections 130 may be formed. Other processes or techniques may be used in other embodiments. In some embodiments, multiple packages 200 are formed on the same substrate 50 and are then singulated to for individual packages 200.

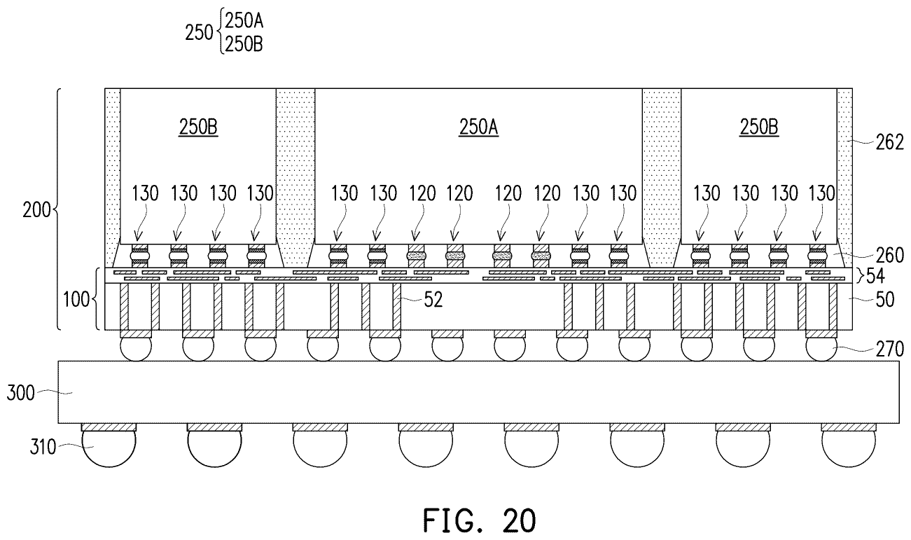

In FIG. 20, a package 200 is attached to a package substrate 300, in accordance with some embodiments. The package 200 may be physically and electrically connected to the package substrate 300 by the conductive connectors 270. The package substrate 300 may comprise conductive pads, conductive routing, and/or other conductive features that provide interconnections and electrical routing. In some embodiments, the package substrate 300 may comprise an interposer, a semiconductor substrate (e.g., a wafer), a redistribution structure, an interconnect substrate, a core substrate, a printed circuit board (PCB), or the like. In some embodiments, the package substrate 300 comprises active and/or passive devices. In other embodiments, the package substrate 300 is free of active and/or passive devices. In some embodiments, an underfill (not illustrated) is formed between the package 200 and the package substrate 300. In some embodiments, conductive connectors 310 are formed on the package substrate 300, which may be similar to the conductive connectors 270 described previously.

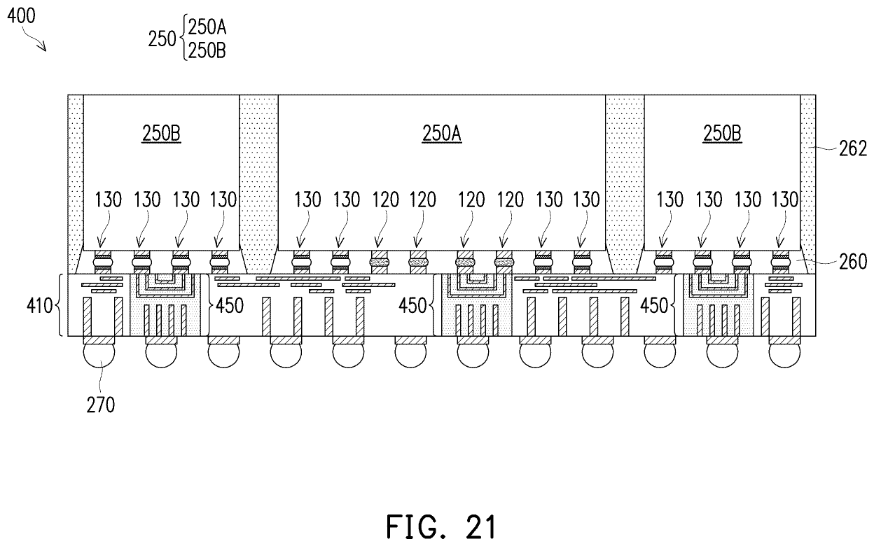

FIG. 21 illustrates a package 400, in accordance with some embodiments. The package 400 is similar to the package 200, except that a redistribution interposer 410 and local interconnects 450 are used instead of an interposer 100. For example, the semiconductor devices 250 may be connected to the redistribution interposer 410 and/or local interconnects 450 by IMC connections 120 and/or by solder connections 130.

The redistribution interposer 410 may be, for example, an organic interposer, a redistribution structure, or the like. The redistribution interposer 410 may include a plurality of redistribution layers formed in a plurality of dielectric layers (not individually illustrated). The redistribution layers may include conductive lines, conductive vias, conductive pads, or the like. The redistribution layers may be formed of a conductive material, such as a metal, such as copper, cobalt, aluminum, gold, combinations thereof, or the like. The redistribution interposer 410 may also include other conductive features, such as metallization patterns, through vias, or the like. In some embodiments, the dielectric layers may comprise a polymer such as polybenzoxazole (PBO), polyimide, a benzocyclobuten (BCB) based polymer, or the like. In other embodiments, the dielectric layers may comprise other suitable dielectric materials, such as silicon oxide or the like. The redistribution layers may be formed using any suitable process, such as deposition, plating, damascene, dual damascene, or the like. In some embodiments, the redistribution interposer is substantially free of active and passive devices. In some cases, the use of a redistribution interposer 410 may reduce manufacturing cost and package size.

The local interconnects 450 may be, for example, chips, chiplets, local silicon interconnects (LSIs), interconnect structures, or the like, that provide additional electrical interconnections within the redistribution interposer 410. For example, the local interconnects 450 may provide electrical connections (e.g., bridging connections) between adjacent semiconductor devices 250. Accordingly, IMC connections 120 and/or solder connections 130 may be formed on the local interconnects 450 in some embodiments. The local interconnects 450 may include conductive features (e.g., conductive lines, vias, pads, or the like) formed in dielectric layers. The conductive features may be formed using suitable techniques, such as damascene, dual damascene, or the like. For example, in some cases, a local interconnect 450 may comprise an interconnect structure on a substrate, which may have through-substrate vias (TSVs) within, though other local interconnects 450 are possible. The local interconnects 450 may or may not include passive devices or active devices. The local interconnects 450 shown in FIG. 21 are illustrative examples, and local interconnects 450 may have a different arrangement, number, configuration, or size than shown. In other embodiments, local interconnects 450 are formed in an interposer similar to the interposer 100 described previously.

Embodiments of the present disclosure have some advantageous features. Forming a package using both fully IMC connections and partially IMC connections between semiconductor devices and an interposer can allow the benefits of both of these types of connections to be utilized within the same package. For example, fully IMC connections can tolerate high current densities, and partially IMC connections are robust to physical and thermal stresses. Thus, in the embodiments described herein, fully IMC connections can be used in relatively low-stress regions and/or where high current densities are important, and partially IMC connections can be used in relatively high-stress regions and/or where high current densities are less important. In this manner, by utilizing both fully IMC connections and partially IMC connections, a package may have improved electrical performance, improved robustness, and improved thermal tolerance. In some embodiments, a semiconductor device may be connected using both types of connections.

In an embodiment of the present disclosure, a method includes forming a first conductive pillar on an interposer; forming a second conductive pillar on the interposer, wherein the second conductive pillar includes a barrier layer; bonding a first semiconductor device to the first conductive pillar by a first bonding region that includes more inter-metallic compound than solder; and bonding the first semiconductor device to the second conductive pillar by a second bonding region that includes more solder than inter-metallic compound. In an embodiment, the first conductive pillar is copper. In an embodiment, the barrier layer is cobalt or nickel. In an embodiment, the first conductive pillar is formed before the second conductive pillar. In an embodiment, forming the second conductive pillar includes forming a copper pillar and depositing the barrier layer on the copper pillar. In an embodiment, bonding the first semiconductor device to the second conductive pillar includes depositing a solder layer on the second conductive pillar; placing a third conductive pillar of the first semiconductor device on the solder layer, wherein the third conductive pillar includes a barrier layer; and performing a reflow process. In an embodiment, the method includes forming a fourth conductive pillar on the interposer; and bonding a second semiconductor device to the fourth conductive pillar by a third bonding region that includes more solder than inter-metallic compound. In an embodiment, the first bonding region is free of solder. In an embodiment, less than 10% of the second bonding region is inter-metallic compound.

In an embodiment of the present disclosure, a method includes performing a first deposition process to form first metal pillars over a substrate; performing a second deposition process to form second metal pillars over the substrate; performing a third deposition process to form a barrier layer on the second metal pillars; depositing solder material on the first metal pillars and on the second metal pillars; and bonding dies to the first metal pillars and to the second metal pillars, which includes: placing the dies on the solder material; and performing a reflow process, wherein after performing the reflow process the solder material on the first metal pillars includes more inter-metallic compound than the solder material on the second metal pillars. In an embodiment, the first metal pillars are free of the barrier layer. In an embodiment, a die is bonded to both a first metal pillar and a second metal pillar. In an embodiment, the inter-metallic compound includes Cu₃Sn or Cu₆Sn₅. In an embodiment, at least one second metal pillar is a dummy pillar. In an embodiment, the first metal pillars is closer to the center of the substrate than the second metal pillars.

In an embodiment of the present disclosure, a package includes an interposer; and a semiconductor device attached to the interposer by a first connection and a second connection, wherein the first connection comprises a fully inter-metallic compound region sandwiched between first conductive features, wherein the second connection comprises a solder region sandwiched between second conductive features, wherein the second conductive features include a barrier layer. In an embodiment, a total height of the first conductive features of a first connection is between 35% and 60% of a total height of that first connection. In an embodiment, an average height of the first connection and the second connection is between 35 μm and 60 μm. In an embodiment, the second conductive features include a barrier layer on copper pillar. In an embodiment, the first connection is adjacent a first edge of the semiconductor device and the second connection is adjacent a second edge of the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
an interposer comprising a first conductive pillar and a second conductive pillar;
a semiconductor device comprising a third conductive pillar and a fourth conductive pillar;
a first conductive material bonding the first conductive pillar to the third conductive pillar; and
a second conductive material bonding the second conductive pillar to the fourth conductive pillar, wherein the composition of the second conductive material is different than the composition of the first conductive material.

2. The package of claim 1 further comprising a barrier layer between the first conductive material and the first conductive pillar.

3. The package of claim 2, wherein the barrier layer comprises cobalt or nickel.

4. The package of claim 1, wherein the first conductive material comprises a larger percent of tin than the second conductive material.

5. The package of claim 1, wherein the first conductive pillar and the third conductive pillar have a smaller height than the second conductive pillar and the fourth conductive pillar.

6. The package of claim 1, wherein the third conductive pillar and the fourth conductive pillar are adjacent.

7. The package of claim 1 further comprising an underfill surrounding the first conductive material and the second conductive material.

8. The package of claim 1, wherein the second conductive material comprises an inter-metallic compound of copper and tin.

9. The package of claim 1, wherein the first conductive material comprises a copper-free region.

10. A structure comprising:
a first semiconductor device;
a second semiconductor device over the first semiconductor device;
a first conductive connector that connects the first semiconductor device to the second semiconductor device, wherein the first conductive connector comprises a first bonding region that comprises at least 90% inter-metallic compound; and
a second conductive connector that connects the first semiconductor device to the second semiconductor device, wherein the second conductive connector comprises a second bonding region that comprises at least 90% solder.

11. The structure of claim 10, wherein the first conductive connector further comprises a first copper pillar underneath the first bonding region.

12. The structure of claim 10, wherein the second conductive connector further comprises a second copper pillar underneath the second bonding region.

13. The structure of claim 12, wherein the second conductive connector further comprises a barrier layer that separates the second copper pillar from the second bonding region.

14. The structure of claim 10, wherein the inter-metallic compound comprises Cu₃Sn or Cu₆Sn₅.

15. The structure of claim 10, wherein the first conductive connector and the second conductive connector have the same height.

16. A method comprising:
depositing a first layer of a first metal on a substrate;
depositing a second layer of the first metal on the substrate;
depositing a second metal on the first layer of the first metal;
depositing a first layer of a third metal on the second metal and a second layer of the third metal on the second layer of the first metal;
attaching a semiconductor device to the first layer of the third metal and the second layer of the third metal; and
performing a reflow process on the first layer of the third metal and the second layer of the third metal.

17. The method of claim 16, wherein the reflow process forms a compound on the second layer of the first metal that comprises the first metal and the third metal.

18. The method of claim 16, wherein, after performing the reflow process, a region of the third metal on the second metal remains free of the first metal.

19. The method of claim 16, wherein the third metal is solder.

20. The method of claim 16, wherein the first metal is copper.
